(19) United States
(12) Patent Application Publication
(10) Pub. No.: US 2026/0313819 A1
(43) Pub. Date: Oct. 8, 2026

(54) MOTION MODULE

(71) Applicant: FIVETECH TECHNOLOGY INC., New Taipei City (TW)

(72) Inventors: TING-JUI WANG, New Taipei City (TW); CHIA-CHING LIAO, New Taipei City (TW)

(73) Assignee: FIVETECH TECHNOLOGY INC., New Taipei City (TW)

(21) Appl. No.: 19/554,683

(22) Filed: Mar. 3, 2026

(30) Foreign Application Priority Data
Apr. 2, 2025 (TW) 114112731
Sep. 12, 2025 (TW) 114135142

(51) Int. Cl. H05K 7/14

(52) U.S. Cl. CPC H05K 7/1407; H05K 7/1421

(57) ABSTRACT

A motion module configured to fasten an object to a fixed object includes a body, a fastener, a linkage member and a fixing member. The body is slidably connected to the object and formed with a sliding limit structure. The fastener is pivotally connected to the body and formed with a fastening region and a linkage structure, and the fastening region is configured to be fastened to at least one part of the fixed object. The linkage member is connected to the body and slidably disposed on the linkage structure. The fixing member is slidably disposed on the sliding limit structure and fixed relative to the object.

### CROSS-REFERENCE TO RELATED APPLICATION

This non-provisional application claims priority under 35 U.S.C. § 119(a) on Patent Application No(s). 114112731 filed in Taiwan, R.O.C. on Apr. 2, 2025, and Patent Application No(s). 114135142 filed in Taiwan, R.O.C. on Sep. 12, 2025, the entire contents of which are hereby incorporated by reference.

### BACKGROUND OF THE INVENTION

### 1. Field of the Invention

The disclosure relates to a motion module, and in particular, to a motion module capable of preventing an object in a coupled state from being separated from a fixed object.

### 2. Description of the Related Art

In the prior art, when an object is coupled to a fixed object, the object can be inserted into a slot or a hole of the fixed object through an insertion structure of the object.

However, when the object is in the coupled state, since the object is connected to the fixed object simply through the insertion structure, if the object is disturbed by external force or collides with another object, it may be separated from the fixed object, causing damage to the object.

### BRIEF SUMMARY OF THE INVENTION

The disclosure provides a motion module capable of preventing an object in a coupled state from being separated from a fixed object, so as to achieve the effects of easy coupling, disassembly and protection of the object.

The disclosure provides a motion module configured to fasten an object to a fixed object. The motion module includes a body and a fastener. The body is slidably connected to the object and formed with a sliding limit structure. The fastener is pivotally connected to the body and formed with a fastening region.

The disclosure provides another motion module configured to fasten an object to a fixed object. The motion module includes a body, a fastener, a linkage member and a fixing member. The body is slidably connected to the object and formed with a sliding limit structure. The fastener is pivotally connected to the body and formed with a fastening region and a linkage structure, and the fastening region is configured to be fastened to at least one part of the fixed object. The linkage member is connected to the body and slidably disposed on the linkage structure. The fixing member is slidably disposed on the sliding limit structure and fixed relative to the object.

In addition, the disclosure further provides another motion module, configured to fasten an object to a fixed object. The motion module includes a body, a fastener, a linkage member and a fixing member. The body is slidably connected to the object and formed with a sliding limit structure. The fastener is pivotally connected to the body and formed with a fastening region. The fixing member is slidably disposed on the sliding limit structure and fixed relative to the object.

Optionally, the body is configured to slide along a coupling direction to drive the fastener to pivot.

Optionally, the motion module further includes an elastic member, and the elastic member is disposed between the body and the object or between the body and an intermediate member.

Optionally, the body includes a base, and the sliding limit structure is formed on the base.

Optionally, the body further includes a stop portion, and the stop portion is connected to a base and deflected relative to the base.

Optionally, the body includes a stop portion and an operating portion, and the operating portion is connected to the stop portion and deflected relative to the stop portion.

Optionally, the body includes a driving portion, and a linkage member is fixedly disposed on the driving portion.

Optionally, the fastener includes a guide structure, and the guide structure is configured to selectively abut against a pushing member of the fixed object.

Optionally, the fastener further includes a fastening hook, and the fastening region is formed between the fastening hook and the guide structure.

Optionally, the motion module further includes a pivot member, and the fastener is pivotally connected to the object through the pivot member.

Optionally, the motion module further includes an intermediate member, where the intermediate member is disposed between the body and the object and fixed relative to the object, and the fastener is pivoted to the intermediate member through the pivot member.

Optionally, the intermediate member is formed with a fixing hole, and the fixing member is fixedly disposed in the fixing hole.

Optionally, the motion module further includes an intermediate member, and the intermediate member is disposed between the body and the object and formed with a plurality of fixing holes.

Optionally, a plurality of the sliding limit structures and a plurality of the fixing members are provided, respectively, the plurality of sliding limit structures are disposed at intervals, and each of the plurality of fixing members is disposed on each of the plurality of sliding limit structures.

Optionally, the motion module further includes a locking member. The body is further formed with a locking portion, and the locking member runs through the locking portion.

Optionally, the body further includes a pulling portion, and the pulling portion is configured for a user to pull so as to slide the body.

Optionally, one of the object and a fixed object is a detachable electronic device, a computer, a chip, a heat dissipation component, a plastic member or a metal member, and the other of the object and the fixed object is a chassis, a motherboard, a cabinet, a slide rail or a wall.

In addition, the disclosure further provides another motion module, configured to fasten an object to a fixed object and including a body, a fastener, a linkage member and a fixing member. The body is slidably connected to the object, and the body includes a driving portion and formed with a sliding limit structure. The fastener is pivotally connected to the body. The fastener includes a driven portion and is formed with a fastening region, and the fastening region is configured to be fastened to at least one part of the fixed object. The linkage member is pivotally connected to the body and connected to the driving portion and the driven portion. The fixing member is slidably disposed on the sliding limit structure and fixed relative to the object.

Optionally, the driving portion includes a rack. The driven portion includes a plurality of engaging teeth. The linkage member is a gear and engages with the rack and the engaging teeth.

Optionally, the body is slidably connected to an intermediate member. The body includes a driving portion. The fastener includes a fastening portion and a driven portion. The driven portion engages with the driving portion so as to enable the fastening portion to perform fastening or unfastening.

Optionally, the body includes a driving portion. The fastener includes a fastening portion and a driven portion. The driven portion engages with the driving portion so as to enable the fastening portion to perform fastening or unfastening.

In addition, the disclosure further provides a motion device. The motion device is applicable to an object and includes two motion modules and a locking member. Each motion module includes a body, a fastener, a linkage member and a fixing member. The body is slidably connected to the object. The body includes a connecting portion and is formed with a sliding limit structure. The fastener is pivotally connected to the body and is formed with a fastening region, and the fastening region is configured to be fastened to at least one part of the fixed object. The linkage member is connected to the body and the fastener. The fixing member is slidably disposed on the sliding limit structure and fixed relative to the object. The locking member runs through the connecting portions of the motion modules and the object.

Optionally, the locking member has a thread and is screwed to the connecting portions and the object. When the locking member rotates relative to the connecting portions or the object, an acting force between the locking member and each of the connecting portions or the object pushes against and drives each of the bodies to slide relative to each of the fasteners.

Optionally, the motion module further includes a locking member, running through the body and the object. The locking member moves to push against the object so as to enable the body to drive the fastener to move.

Optionally, the body further includes a connecting portion and is formed with two sliding limit structures. Two fasteners are connectable to the body and formed with two fastening regions, and the fastening regions are each configured to be fastened to a fixed object. Two fixing members are slidably disposed on the sliding limit structure and fixed relative to the object. A locking member runs through the connecting portion of the motion module and the object. The locking member moves to push against the object so as to enable the body to drive the fasteners to move.

In addition, the disclosure further provides another motion module, configured to fasten an object to a fixed object. The motion module includes a body, a fastener and a fixing member. The body is slidably connected to an intermediate member. The intermediate member includes a base and a driving portion. The fastener is pivoted to the intermediate member. The fastener includes a fastening portion and a driven portion. The driven portion engages with the driving portion so as to enable the fastening portion to perform fastening or unfastening.

Optionally, the driving portion is a rack.

Optionally, the driven portion is a plurality of engaging teeth.

Optionally, the body further includes a stop portion. The stop portion is connected to a base of the body and deflected relative to the base, or the stop portion is bent by 90 degrees or nearly 90 degrees, or the bent stop portion is configured such that the stop portion is operated or used from a front side of the object.

Optionally, the motion module further includes an intermediate member, where the body includes a base, the fastener further includes a driven portion, the base and the driven portion are driven or disposed at an angle of nearly 90 degrees or at 90 degrees, or where the intermediate member is bent or curved to accommodate the driven portion.

In addition, the disclosure further provides a motion method, including: providing a motion module, where the motion module includes a body formed with a sliding limit structure, a fastener pivotally connected to the body and formed with a fastening region and a linkage structure, a linkage member connected to the body and slidably disposed on the linkage structure, and a fixing member slidably disposed on the sliding limit structure; disposing the motion module on an object; abutting the fastener against a fixed object; sliding the body along a coupling direction relative to the object; and enabling the fastener to slide relative to the body and rotate relative to the object such that the fastening region is fastened to at least one part of the fixed object.

In addition, the disclosure further provides a motion method, including: providing a motion module, where the motion module includes a body having a driving portion and formed with a sliding limit structure, a fastener having a driven portion and formed with a fastening region, a linkage member connected to the driving portion and the driven portion, and a fixing member slidably disposed on the sliding limit structure; disposing the motion module on an object; abutting the fastener against a fixed object; sliding the body along a coupling direction relative to the object; and enabling the fastener to slide relative to the body and rotate relative to the object such that the fastening region is fastened to at least one part of the fixed object.

In addition, the disclosure further provides a motion method, including: providing a motion module, where the motion module includes a body formed with a sliding limit structure, a fastener pivotally connected to the body and formed with a fastening region and a linkage structure, and a fixing member slidably disposed on the sliding limit structure; disposing the motion module on an object; abutting the fastener against a fixed object; sliding the body along a coupling direction relative to the object; and enabling the fastener to slide relative to the body and rotate relative to the object such that the fastening region is fastened to at least one part of the fixed object.

In addition, the disclosure further provides a motion method, including: providing a motion module, where the motion module includes a body having a driving portion and formed with a sliding limit structure, a fastener having a driven portion and formed with a fastening region, and a fixing member disposed on the sliding limit structure; disposing the motion module on an object; abutting the fastener against a fixed object; sliding the body along a coupling direction relative to the object; and enabling the fastener to slide relative to the body and rotate relative to the object such that the fastening region is fastened to at least one part of the fixed object.

In addition, the disclosure further provides a motion method, including: providing a motion module, where the motion module includes a body formed with a sliding limit structure, and a fastener pivotally connected to the body and formed with a fastening region and a linkage structure; disposing the motion module on an object; abutting the fastener against a fixed object; sliding the body along a coupling direction relative to the object; and enabling the fastener to slide relative to the body and rotate relative to the object such that the fastening region is fastened to at least one part of the fixed object.

In addition, the disclosure further provides a motion method, including: a body, slidably connected to an object and having a sliding limit structure; a fastener, connectable to the body and formed with a fastening region, the fastening region being configured to be fastened to at least one part of a fixed object; a fixing member, slidably disposed on the sliding limit structure and fixed relative to the object; and a locking member, running through the body of the motion module and the object, the locking member moving to push against the object so as to enable the body to drive the fasteners to move.

In addition, the disclosure further provides a motion method, which provides a motion module. The motion module includes a body and a fastener. The body is slidably connected to an object and has a sliding limit structure. The fastener is connectable to the body and formed with a fastening region, and the fastening region is configured to be fastened to at least one part of a fixed object. The body further includes a stop portion. The stop portion is connected to a base of the body and deflected relative to the base, or the stop portion is bent by 90 degrees or nearly 90 degrees, or the bent stop portion is configured such that the stop portion is operated or used from a front side of the object.

Optionally, the motion method further includes enabling the body to slide along a coupling direction so as to drive the fastener to pivot.

### BRIEF DESCRIPTION OF THE DRAWINGS

FIG. 1 is a schematic front view of a motion module according to an embodiment of the disclosure.

FIG. 2 is a schematic exploded view of FIG. 1.

FIG. 3 is a schematic top view of FIG. 1.

FIG. 4 is a schematic flowchart showing steps of a motion method according to an embodiment of the disclosure.

FIG. 5 is a schematic front view of an object equipped with the motion module of FIG. 1 in a to-be-coupled state relative to a fixed object.

FIG. 6 is a schematic front view when a body in FIG. 5 slides along a coupling direction to a first position.

FIG. 7 is a schematic front view when the body in FIG. 6 slides along the coupling direction to a second position and the object moves along the coupling direction.

FIG. 8 is a schematic front view of an object equipped with the motion module of FIG. 1 in a coupled state relative to a fixed object.

FIG. 9 is a schematic front view when the body in FIG. 8 slides along a removal direction to a third position.

FIG. 10 is a schematic front view when the body in FIG. 9 slides along the removal direction to a fourth position and the object moves along the removal direction.

FIG. 11 is a schematic front view of a motion module according to another embodiment of the disclosure.

FIG. 12 is a schematic front view of a motion module according to yet another embodiment of the disclosure.

FIG. 13 is a schematic top view of a motion device according to an embodiment of the disclosure.

FIG. 14 is a schematic front view of a motion module according to still another embodiment of the Disclosure.

FIG. 15 is a schematic view of a motion device according to another embodiment of the disclosure.

### DETAILED DESCRIPTION OF THE INVENTION

The motion module of embodiments of the disclosure will be further described below with reference to the accompanying drawings.

The foregoing and other technical contents, features and effects of the disclosure will be clearly presented in the following detailed description of preferred embodiments with reference to the accompanying drawings. It is worth mentioning that the directional terms mentioned in the embodiments below, such as up, down, left, right, front or rear, are only directions referring to the accompanying drawings. Therefore, the directional terms used are intended to be illustrative rather than limiting of the disclosure. In addition, in the following embodiments, the same or similar components will use the same or similar reference numerals.

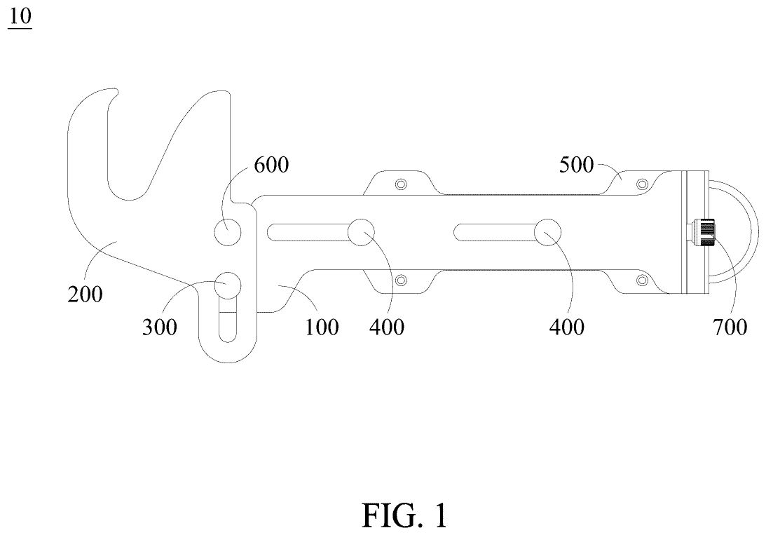

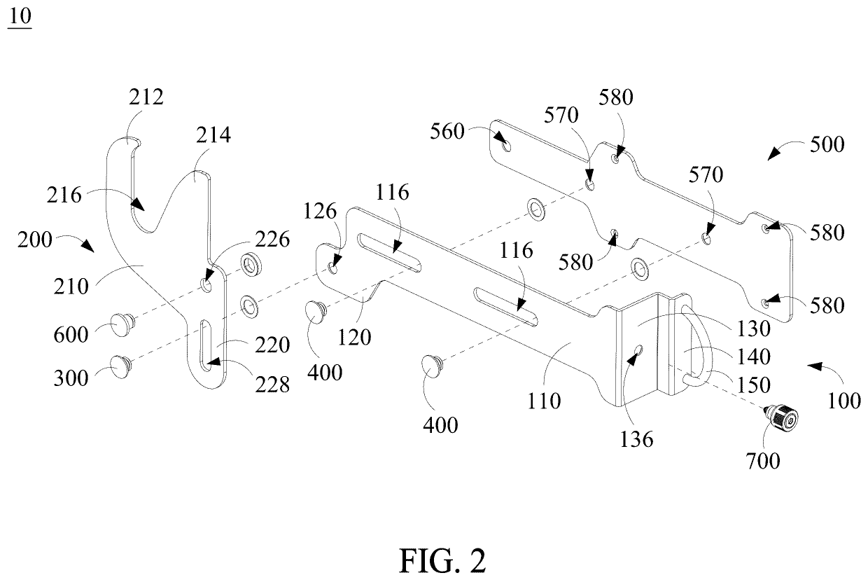

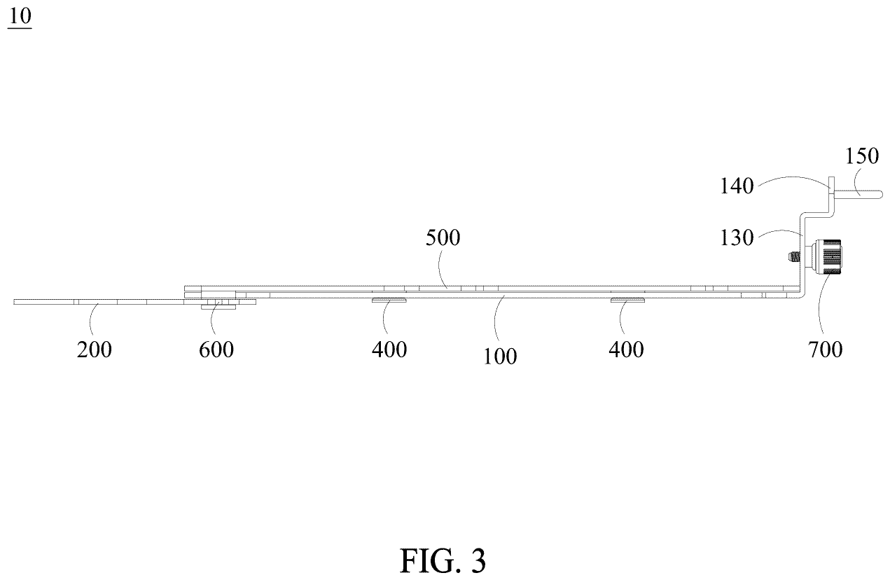

Referring to FIG. 1 to FIG. 3, FIG. 1 is a schematic front view of a motion module according to an embodiment of the disclosure, FIG. 2 is a schematic exploded view of FIG. 1, and FIG. 3 is a schematic top view of FIG. 1. A motion module 10 of this embodiment is configured to fasten an object to a fixed object. The motion module 10 includes a body 100, a fastener 200, a linkage member 300 and at least a fixing member 400. The body 100 is, for example, a plate-like member extending generally along a longitudinal direction and formed with at least one sliding limit structure 116. In this embodiment, two sliding limit structures 116, which are, for example, sliding grooves extending along the longitudinal direction, are provided, and the sliding limit structures 116 are disposed at intervals. The fastener 200 is formed with a fastening region 216 and a linkage structure 228. The fastening region 216 is, for example, a notch configured to fasten the fixed object, and the linkage structure 228 is, for example, a sliding groove. The linkage member 300 is connected to the body 100, and in this embodiment, the linkage member is a screw and is slidably disposed on the linkage structure 228. The number and size of the fixing members 400 correspond to those of the sliding limit structures 116, and in this embodiment, the fixing members are, for example, screws and are respectively disposed on the corresponding sliding limit structures 116.

As shown in FIG. 2, the body 100 may include a base 110, a driving portion 120 and a stop portion 130. The base 110 is configured to serve as a main member connected to the object, and the sliding limit structures 116 are formed on the base 110 at intervals. On the other hand, the driving portion 120 is configured to connect the fastener 200 and formed with a linkage hole 126, and the linkage member 300 runs through the linkage structure 228 and is screwed and fixed in the linkage hole 126 of the driving portion 120. The stop portion 130 is connected to the base 110 and deflected along a transverse direction relative to the base 110, so as to prevent the object in a fastened state from being separated from the fixed object. The driving portion 120 and the stop portion 130 are disposed on two different sides of the base 110. In this embodiment, by way of example, the driving portion 120 is disposed on a bottom side of a front end of the base 110, and the stop portion 130 is disposed on a rear end of the base 110, but the disclosure is not limited thereto. The designer may adjust the arrangement relationship of the driving portion 120 and the stop portion 130 relative to the base 110 according to actual needs such as the specifications of the object to be fastened and the fixed object.

In some possible embodiments, the body 100 further includes an operating portion 140. The operating portion 140 is connected to the stop portion 130 and deflected relative to the stop portion 130. In this embodiment, the operating portion is, for example, a plate disposed on a rear end of the stop portion 130 and extending for a certain distance in the longitudinal direction and the transverse direction respectively, which is convenient for a user to operate the body 100. In addition, in some other embodiments, the body 100 may further include a pulling portion 150. The pulling portion 150 is, for example, a handle disposed on the operating portion 140, and may be circular, square or in other similar shapes suitable for a user to hold, so that the user can slide the body 100 relative to the fastener 200 by pulling the pulling portion 150.

On the other hand, the fastener 200 may include a fastening portion 210. The fastening portion 210 includes a fastening hook 212 and a guide structure 214, and the fastening region 216 is formed between the fastening hook 212 and the guide structure 214. Specifically, when the motion module 10 fastens the object to the fixed object, the fastening hook 212 may adjust the position between the body 100 and the fastener 200 by pushing against a part of the fixed object and fasten this part of the fixed object through the fastening region 216. The guide structure 214 is, for example, a protrusion formed with an arc-shaped outer edge, and may be configured to push against this part of the fixed object when the object is to be unfastened from the fixed object, such that the object smoothly moves away from the fastening region 216. In addition, the fastener 200 further includes a driven portion 220. The driven portion 220 is connected to the fastening portion 210. The linkage structure 228 is formed on the driven portion 220, and the fastener 200 may convert the sliding of the body 100 into the rotation of the fastener 200 through the driven portion 220.

In some possible embodiments, the motion module 10 further includes an intermediate member 500 and a pivot member 600. The intermediate member 500 is configured to be disposed between the body 100 and the object and fixed relative to the object. In this embodiment, the intermediate member is, for example, a plate extending substantially along the longitudinal direction and is formed with an intermediate member pivot hole 560, at least one fixing hole 570 and a plurality of object fixing holes 580. Specifically, the intermediate member pivot hole 560 is, for example, disposed on a front end of the intermediate member 500. The pivot member 600 is, for example, a screw. A part of the driven portion 220 between the fastening region 216 and the linkage structure 228 is further formed with a fastener pivot hole 226, and the pivot member 600 sequentially runs through the fastener pivot hole 226 and the intermediate member pivot hole 560, so as to pivot the fastener 200 to the intermediate member 500. On the other hand, the number and position of the fixing holes 570 correspond to those of the sliding limit structures 116, and each fixing member 400 runs through the corresponding sliding limit structure 116 and is screwed and fixed in the corresponding fixing hole 570 in the intermediate member 500, such that the body 100 is slidably connected to the object. Through this arrangement, the user does not need to provide holes for pivoting the fastener 200 and fixing the fixing member 400 in the object, and the large number of object fixing holes 580 can be used for sharing the weight of the motion module 10 itself and the load during actuation. Moreover, the body 100 and the fastener 200 can be prevented from wearing the object during the actuation, thereby effectively protecting the object and prolonging the service life of the motion module 10.

It is worth mentioning that, in this embodiment, by way of example, the motion module 10 has the intermediate member 500 as a connecting intermediary component of the body 100 and a pivot medium of the fastener 200. However, the disclosure is not limited thereto. In other possible embodiments, the object may be provided with holes for pivoting or fixation to pivot the linkage member 300 to the object and fixedly dispose the fixing member 400 to the object. Alternatively, the body 100 and the fastener 200 may be disposed on the object having a slide rail and/or a pivot, or the intermediate member 500 may even be snap-fitted, bonded, adsorbed or integrally formed with the object. All of these are optional methods for coupling the motion module 10 to the object.

Preferably, the motion module 10 further includes a locking member 700, and the body 100 is further formed with a locking portion 136. In this embodiment, the locking portion 136 is, for example, a hole and is formed in the stop portion 130, and the object is formed with a hole at the corresponding position to be fixed with the locking member 700. Thereby, when the user wants to fix the motion module 10 relative to the object, the locking member 700 may be allowed to run through the locking portion 136 and then locked in the hole of the object, thereby fixing the body 100 to the object. When the user wants to operate the motion module 10, it is only required to remove the locking member 700 from the object, so that the body 100 can return to a state of being slidable relative to the object.

It is worth mentioning that, in this embodiment, the locking member 700 is a spring screw, the hole of the object is a screw hole to be screwed with the spring screw, and the locking member 700 may be pulled out relative to the body 100. Thereby, when the user undoes the screwing relationship between the locking member 700 and the object, the locking member 700 can make the shank of the screw completely separated from the screw hole by virtue of the elastic force of the internal spring, thereby improving the convenience of decoupling the body 100 from the object. In addition, since the locking member 700 is easily lost after being removed from the body 100, by using the spring screw, the locking member 700 may be directly combined to the body 100, and may be locked to the object or unlocked from the object by inserting the locking member 700 into the body 100/pulling the locking member out of the body. Furthermore, the user may directly pull the locking member 700 to operate the body 100 and the fastener 200. In other words, in some embodiments where the motion module 10 does not have the operating portion 140, the designer may enhance the upper limit of pulling and springback times of the locking member 700 and the connection relationship between the locking member 700 and the body 100, and directly use the locking member 700 as a component for operating the body 100, which is not limited in the disclosure.

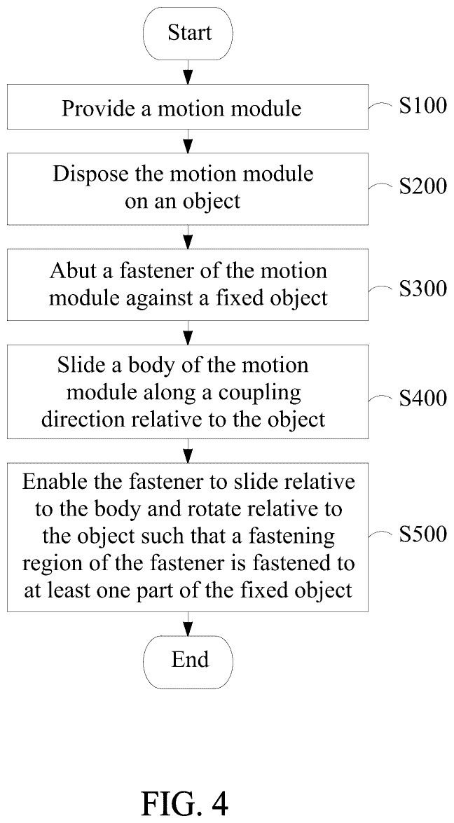

Referring to FIG. 4, FIG. 4 is a schematic flowchart showing steps of a motion method according to an embodiment of the disclosure. The motion method of this embodiment includes: providing a motion module (step S100), where the motion module includes a body formed with a sliding limit structure, a fastener pivotally connected to the body and formed with a fastening region and a linkage structure, a linkage member connected to the body and slidably disposed on the linkage structure, and a fixing member slidably disposed on the sliding limit structure; disposing the motion module on an object (step S200); abutting the fastener against a fixed object (step S300); sliding the body along a coupling direction relative to the object (step S400); and enabling the fastener to slide relative to the body and rotate relative to the object such that the fastening region is fastened to at least one part of the fixed object (step S500).

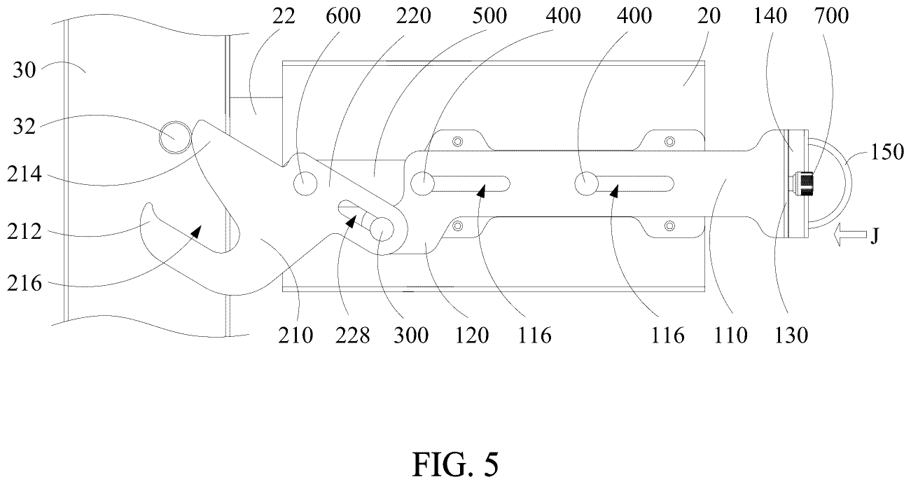

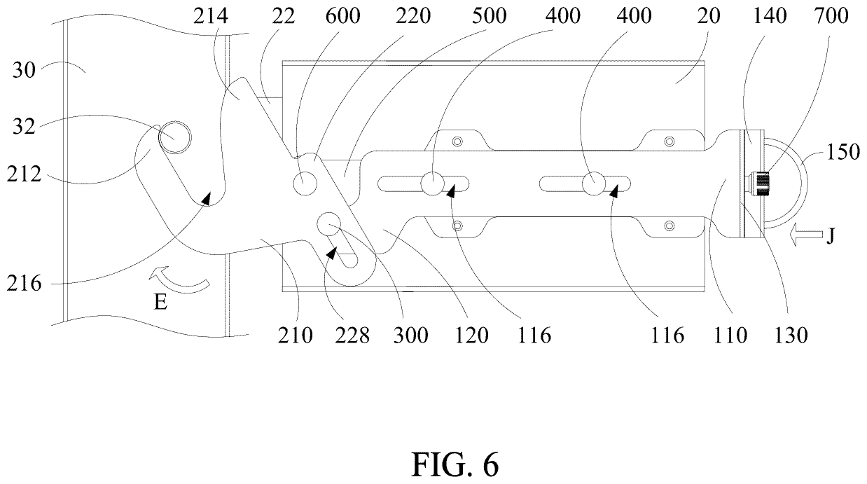

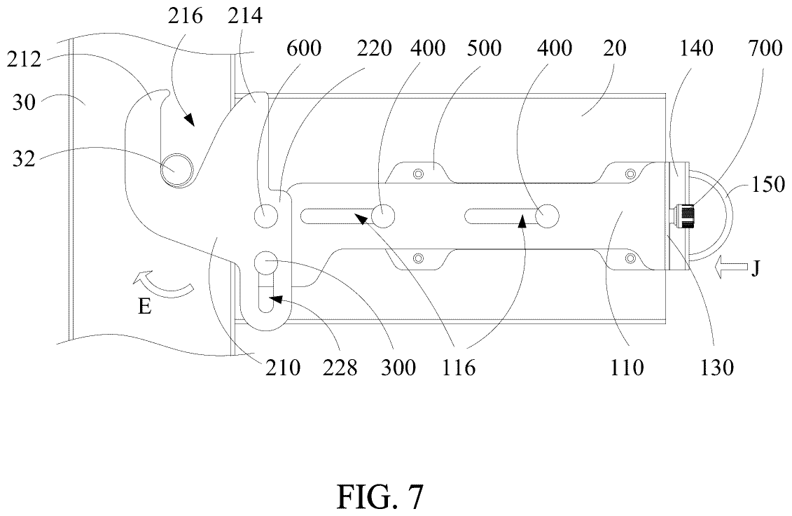

The process of how the motion module 10 of this embodiment fastens an object to a fixed object will be described in detail below. Referring to FIG. 5 to FIG. 7, FIG. 5 is a schematic front view of an object equipped with the motion module of FIG. 1 in a to-be-coupled state relative to a fixed object, FIG. 6 is a schematic front view when a body in FIG. 5 slides along a coupling direction to a first position, and FIG. 7 is a schematic front view when the body in FIG. 6 slides along the coupling direction to a second position and the object moves along the coupling direction. In this embodiment, the object 20 may be a detachable electronic device, such as a USB hard drive, an external hard drive, a card reader, a computer mainframe or a server, and has an insertion portion 22, and the motion module 10 fixedly disposes the intermediate member 500 onto the object 20 through fixing components such as screws or rivets running through the object fixing holes 580. On the other hand, the fixed object 30 is, for example, a chassis, a motherboard, a cabinet, a slide rail or a wall, and has a pushing member 32 and is formed with an insertion slot (not shown). The pushing member 32 is, for example, of a protruding cylindrical structure configured to push and guide the fastener 200. However, in other possible embodiments, the object 20 may also be a chip, a heat dissipation component, a plastic member or a metal member, and the object 20 and the fixed object 30 may be interchanged with each other.

When the user wants to fasten the object 20 to the fixed object 30, as shown in FIG. 5, the object 20 and the motion module 10 may be moved close to the fixed object 30 along a coupling direction J until the guide structure 214 abuts against the pushing member 32. Next, as shown in FIG. 6, when the body 100 slides along the coupling direction J relative to both the object 20 and the fixed object 30, the fastening portion 210 generates a moment based on the push of the pushing member 32, the driven portion 220 also generates a moment in the same direction due to the push of the linkage member 300 in the coupling direction J, and the fixing member 400 is limited by the sliding limit structure 116 such that the body 100 and the object 20 are relatively fixed in the vertical direction. Under the combined action of these components, the fastener 200 slides along the coupling direction J, and at the same time, pivots along a fastening direction E with the pivot member 600 as a fulcrum, such that the fastening hook 212 hooks the pushing member 32 and a gap is formed between the guide structure 214 and the pushing member 32.

Then, the object 20 and the motion module 10 may be further slid synchronously along the coupling direction J, such that the linkage member 300 slides upward along the linkage structure 228 and pushes the fastener 200 upward. At this time, the object 20 may be inserted into the insertion slot of the fixed object 30 through the insertion portion 22. Finally, the body 100 is further slid along the coupling direction J relative to the object 20 and the fixed object 30 by using the operating portion 140, such that the fastener 200 pivots to a target position (i.e., the position where the pushing member 32 is located in the deepest part of the fastening region 216 in FIG. 7) along the fastening direction E, and the stop portion 130 closely abuts against the rear side of the object 20, thereby completing the whole fastening process. In the fastened state, when the object 20 is subjected to an external force opposite to the coupling direction J, since the rear side of the object 20 is pushed by the stop portion 130 and the pushing member 32 and the right side of the fastening hook 212 are locked to each other, the body 100, the fastener 200 and the fixed object 30 are relatively fixed in the coupling direction J, so that the object 20 can be prevented from being separated from the fixed object 30. In order to enhance the fixation between the body 100 and the object 20, the user may further lock the locking member 700 into the hole of the object 20, thereby preventing the body 100 from sliding relative to the object 20 along a direction opposite to the coupling direction J.

In addition, the stop portion 130 may be bent by 90 degrees or nearly 90 degrees, or the bent stop portion 130 is configured such that the user can operate or use the stop portion 130 from the front side of the object 20 (for example, the front side in FIG. 6).

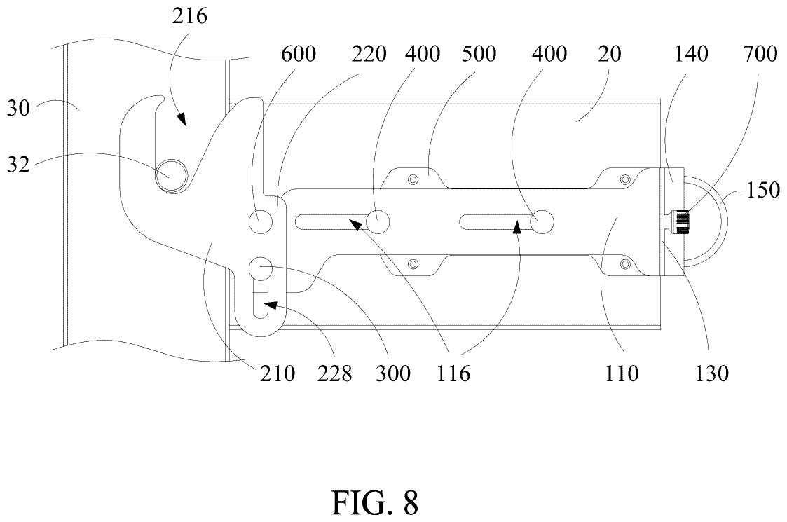

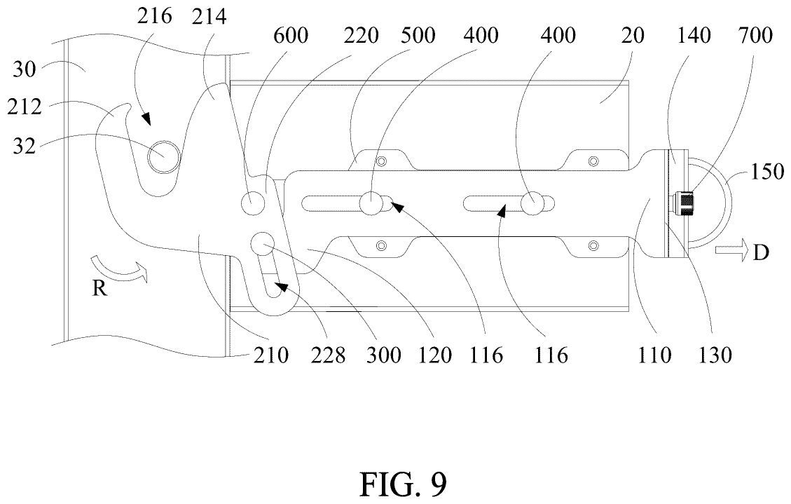

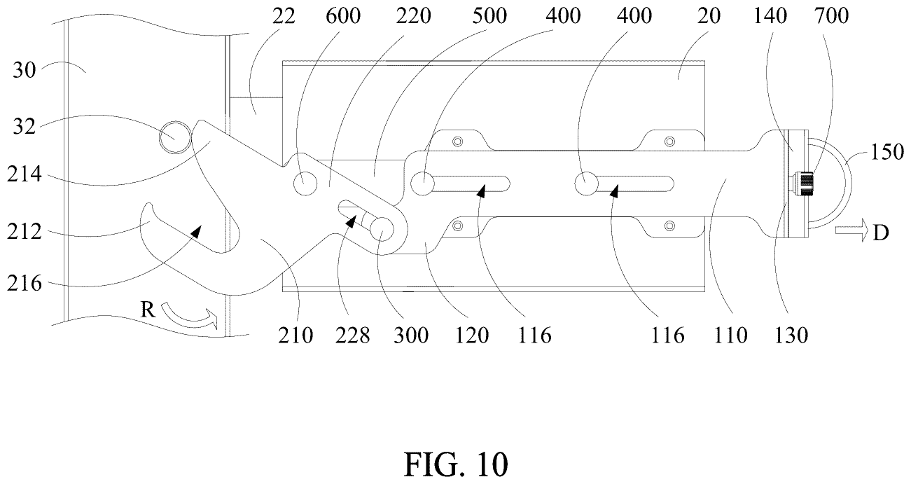

Referring to FIG. 8 to FIG. 10, FIG. 8 is a schematic front view of an object equipped with the motion module of FIG. 1 in a coupled state relative to a fixed object, FIG. 9 is a schematic front view when the body in FIG. 8 slides along a removal direction to a third position, and FIG. 10 is a schematic front view when the body in FIG. 9 slides along the removal direction to a fourth position and the object moves along the removal direction When the user wants to remove the object 20 from the fixed object 30, first, the locking member 700 may be unlocked from the object 20, and the operating portion 140 is pulled such that the body 100 slides relative to the object 20 and the fixed object 30 along the removal direction D in FIG. 9. At this time, the body 100 is limited by the fixing member 400 and thus fixed relative to the object 20 in a height direction, and a moment is generated as the linkage member 300 pulls the fastener 200. Then, the fastener 200 pivots along the unfastening direction R in FIG. 9 with the pivot member 600 as a fulcrum under the action of the moment, so that the guide structure 214 and the pushing member 32 push against each other, and thus, the moment of the fastener pivoting along the unfastening direction R increases. In the process that the pushing member 32 pushes against the outer edge of the guide structure 214, the linkage member 300 slides downward along the linkage structure 228, so that the fastener 200 not only slides along the removal direction D and rotates along the unfastening direction R, but also moves downward, until the pushing member 32 is completely separated from the fastening region 216. Thereby, the user may hold the object 20 and move the object along the removal direction D, so that the insertion portion 22 is separated from the insertion slot of the fixed object 30, thereby completing the removal of the object 20.

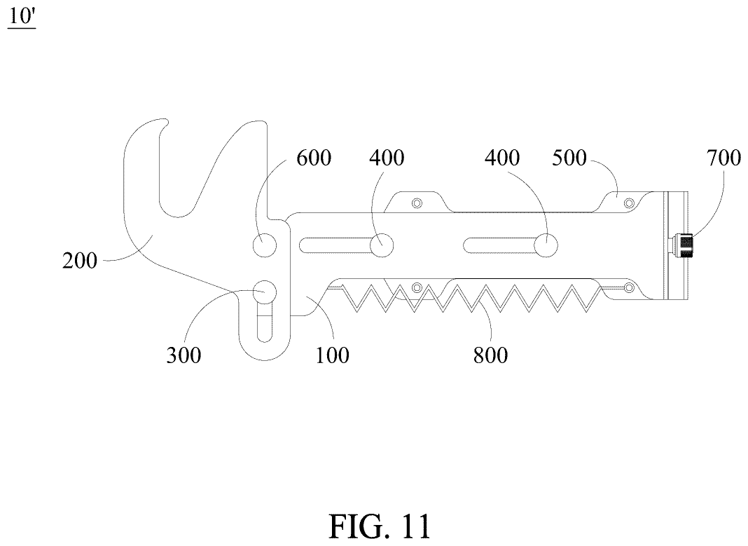

Referring to FIG. 11, FIG. 11 is a schematic front view of a motion module according to another embodiment of the disclosure. A motion module 10′ of this embodiment is substantially the same as the motion module 10 of the previous embodiment, except that: the motion module 10′ further includes an elastic member 800, and the elastic member 800 is disposed between the body 100 and the object 20.

Specifically, in order to make the motion module 10′ to automatically return to its original position after the body 100 slides along the coupling direction J and is fastened to the fixed object 30 or after the body 100 slides along the removal direction D and is unfastened from the fixed object 30, the motion module 10′ of this embodiment further includes an elastic member 800. The elastic member 800 is, for example, a linear spring and is disposed between the body 100 and the object 20. In this embodiment, by way of example, two ends of the elastic member 800 are respectively connected to the driving portion 120 and the intermediate member 500 on the right side, but the specific connection position of the elastic member 800 is not limited thereto. Through this arrangement, when the user slides the body 100 along the coupling direction J relative to the object 20 and fastens the pushing member 32 into the fastening region 216, the user only needs to release the operating portion 140 such that the elastic force accumulated by the elastic member 800 drives the whole body 100 to slide along the coupling direction J. In this way, the body 100 can retract to the surface of the object 20 without manual operation, thereby improving the convenience in use.

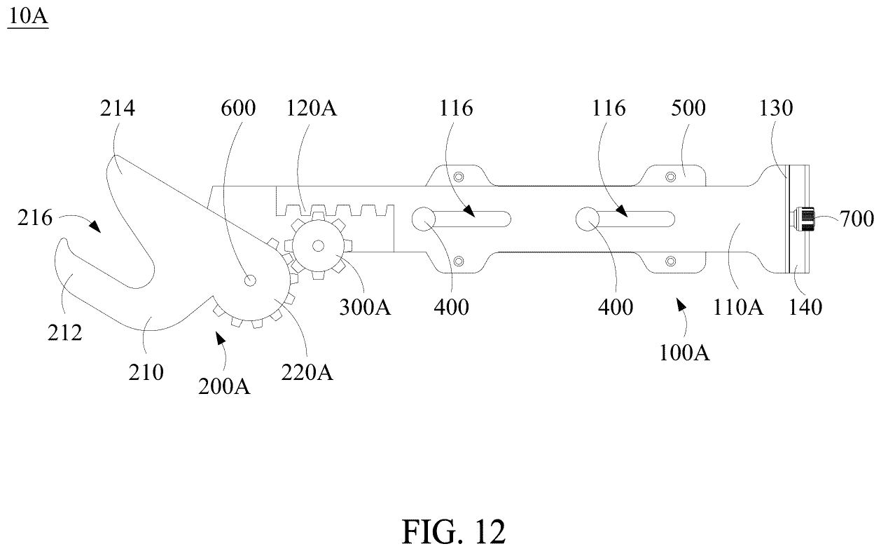

Referring to FIG. 12, FIG. 12 is a schematic front view of a motion module according to yet another embodiment of the disclosure. A motion module 10A of this embodiment is substantially the same as the motion module 10 of the first embodiment, except that: a fastener 200A of the motion module 10A does not have a linkage structure, and a linkage member 300A is pivotally connected to the object and connected to a driving portion 120A and a driven portion 220A.

Specifically, compared with the motion module 10 of the first embodiment in which the sliding of the body 100 is converted into the pivoting of the fastener 200 through the sliding relationship between the linkage member 300 and the linkage structure 228, in the motion module 10A of this embodiment, the sliding of a body 100A may be converted into the pivoting of the fastener 200A through the engaging relationship between the body 100A and the linkage member 300A and the engaging relationship between the linkage member 300A and the fastener 200A. As shown in FIG. 12, the motion module 10A includes the body 100A, the fastener 200A, the linkage member 300A and the fixing member 400. The body 100A is, for example, slidably connected to the intermediate member 500 and includes a base 110A and a driving portion 120A, and the driving portion 120A may include a rack extending along a coupling direction J. The fastener 200A is, for example, pivoted to the intermediate member 500 through the pivot member 600 and includes the fastening portion 210 and a driven portion 220A, and the driven portion 220A includes a plurality of engaging teeth disposed along a periphery. The linkage member 300A is, for example, a spur gear and is pivoted to the intermediate member 500, and the linkage member 300A engages with both the rack of the driving portion 120A and the engaging teeth of the driven portion 220A.

Thereby, when the user slides the body 100A along the coupling direction J relative to the object 20, the driving portion 120A may drive the linkage member 300A to pivot through the engaging relationship with the linkage member 300A and further drive the engaging teeth of the driven portion 220A and the whole fastener 200A to pivot, which can also convert the sliding of the body 100A into the pivoting of the fastener 200A. Moreover, since the driving portion 120A, the linkage member 300A and the driven portion 220A are closely linked through the engaging relationship, the pivoting phase of the fastener 200A can be accurately controlled, such that the motion module can be effectively applied to some occasions where the angle of The fastener 200A is highly required.

It is worth mentioning that, in this embodiment, by way of example, the driving portion 120A includes the rack, the driven portion 220A includes the engaging teeth disposed along the periphery and the linkage member 300A is the spur gear, the disclosure is not limited thereto. In some possible embodiments, the driving portion 120A may also include a screw shank, the driven portion 220A may include a rack engaging with the linkage member 300A, and the linkage member 300A may also be a bevel gear, a helical gear or another component having an engaging effect, as long as the sliding of the body 100A can be converted into the pivoting of the fastener 200A.

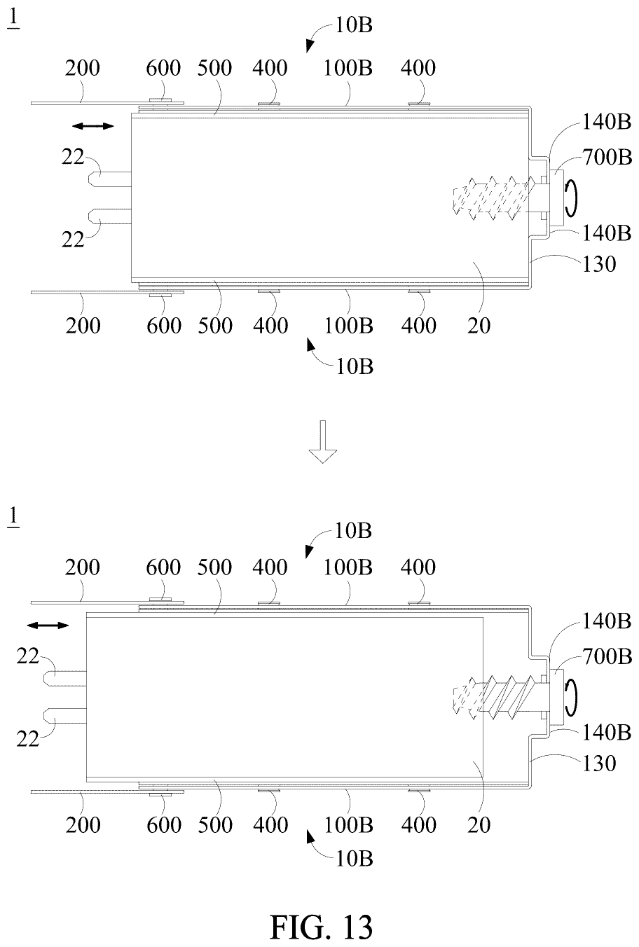

Referring to FIG. 13, FIG. 13 is a schematic top view of a motion device according to an embodiment of the disclosure. The motion device 1 of this embodiment includes two motion modules 10B and a locking member 700B. Each motion module 10B includes a body 100B, the fastener 200, the linkage member 300, the fixing member 400 and the intermediate member 500. The body 100B is slidably connected to an object 20 and formed with a sliding limit structure 116. The fastener 200 is pivotally connected to the body 100B. The linkage member 300 is connected to the body 100B and the fastener 200. The fixing member 400 is slidably disposed on the sliding limit structure 116 and fixed relative to the object 20. The locking member 700B runs through the body 100B. The motion module 10B in this embodiment is different from the motion module 10 of the first embodiment mainly in that: the body 100B of each motion module 10B includes a connecting portion 140B, and the locking member 700B runs through the connecting portions 140B and the object 20.

Specifically, compared with the motion module 10 of the first embodiment in which the body 100 is unlocked from the object 20 by pulling the locking member 700 which is the spring screw, the locking member 700B of the motion device 1 of this embodiment runs through the two motion modules 10B and the object 20, so that the left and right sides of the object 20 may both be fastened to the fixed object 30 and two or more motion modules 10B may be operated at one time through the locking member 700B. In this embodiment, the locking member 700B is, for example, a screw having a thread and is screwed to the connecting portions 140B and the object 20. When the locking member 700B rotates relative to the connecting portions 140B or the object 20, an acting force between the locking member 700B and each of the connecting portions 140B or the object 20 may push against and drive each of the bodies 100B to slide relative to each of the fasteners 200, thereby achieving the locking and fastening effects.

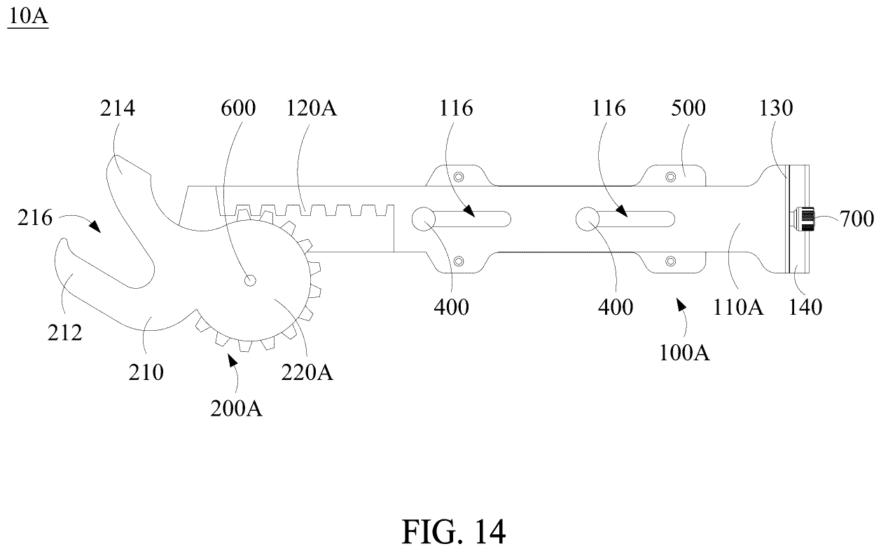

Referring to FIG. 14, FIG. 14 is a schematic front view of a motion module according to still another embodiment of the disclosure. A motion module 10A of this embodiment is substantially the same as the motion module 10A of FIG. 12, except that the linkage member 300A is not required in this embodiment.

Specifically, the motion module 10A of this embodiment includes the body 100A, the fastener 200A and the fixing member 400. The body 100A is, for example, slidably connected to the intermediate member 500 and includes a base 110A and a driving portion 120A, and the driving portion 120A may include a rack extending along a coupling direction J. The fastener 200A is, for example, pivoted to the intermediate member 500 through the pivot member 600 and includes the fastening portion 210 and the driven portion 220A, and the driven portion 220A includes a plurality of engaging teeth disposed along a periphery. The linkage member 300A is, for example, a spur gear and is pivoted to the intermediate member 500, and the engaging teeth of the driven portion 220A engage with the rack of the driving portion 120A.

Thereby, when the user slides the body 100A along the coupling direction J relative to the object 20, the driving portion 120A may drive the engaging teeth of the driven portion 220A and the whole fastener 200A to pivot, which can also convert the sliding of the body 100A into the pivoting of the fastener 200A. Moreover, since the driving portion 120A, the linkage member 300A and the driven portion 220A are closely linked through the engaging relationship, the pivoting phase of the fastener 200A can be accurately controlled, such that the motion module can be effectively applied to some occasions where the angle of the fastener 200A is highly required and the required fastening or unfastening can be performed through the fastening portion 210.

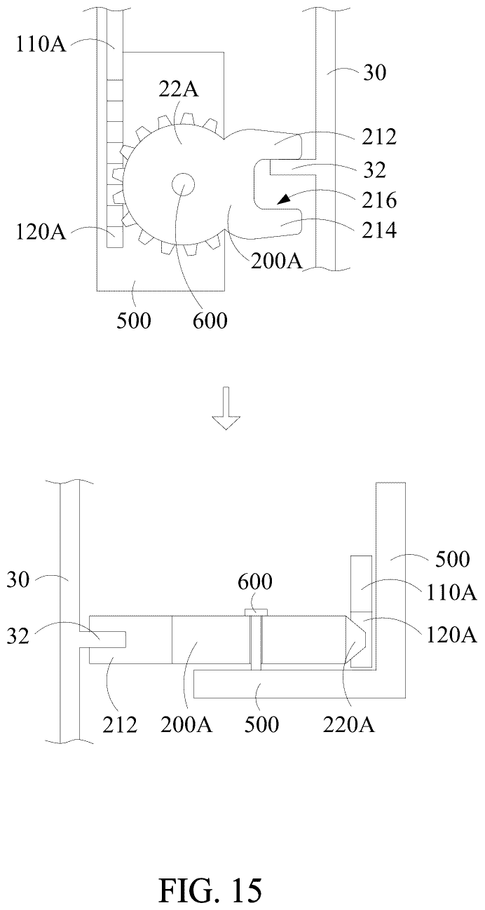

Referring to FIG. 15, the base 110A and the driven portion 220A are driven or disposed at an angle of nearly 90 degrees or at 90 degrees, or the intermediate member 500 is bent or curved to accommodate the driven portion 220A. Thereby, the driving portion 120A of the base 110A drives the driven portion 220A, such that the fastening hook 212 and the guide structure 214 hook the pushing member 32 to perform fastening, or the fastening hook 212 and the guide structure 214 push the pushing member 32 to perform unfastening.

Based on the above, according to the motion module and the motion method of the disclosure, the body can slide to different positions relative to the object, and the fastener is driven through the linkage member so as to selectively engage with or disengage from the fixed object, thereby achieving the effects of easy coupling, disassembly and protection of the object.

While the present disclosure has been described by means of specific embodiments, numerous modifications and variations could be made thereto by those skilled in the art without departing from the scope and spirit of the present disclosure set forth in the claims.

What is claimed is:

1. A motion module, comprising:
a body, slidably connected to an object and formed with a sliding limit structure; and
a fastener, pivotally connected to the body and formed with a fastening region.

2. The motion module according to claim 1, wherein the fastener is connected to the body and formed with the fastening region or a linkage structure, and the fastening region is configured to be fastened to at least one part of a fixed object; or the motion module further comprises a linkage member, and the linkage member is connected to the body and slidably disposed on the linkage structure; or the motion module further comprises a fixing member, and the fixing member is slidably disposed on the sliding limit structure.

3. The motion module according to claim 1, wherein the body is configured to slide along a coupling direction to drive the fastener to pivot.

4. The motion module according to claim 1, further comprising an elastic member, wherein the elastic member is disposed between the body and the object or between the body and an intermediate member.

5. The motion module according to claim 1, wherein the body comprises a base, and the sliding limit structure is formed on the base.

6. The motion module according to claim 1, wherein the body further comprises a stop portion, wherein the stop portion is connected to a base of the body and deflected relative to the base, or the stop portion is bent by 90 degrees or nearly 90 degrees, or the bent stop portion is configured such that the stop portion is operated or used from a front side of the object.

7. The motion module according to claim 1, wherein the body comprises a stop portion and an operating portion, and the operating portion is connected to the stop portion and deflected relative to the stop portion.

8. The motion module according to claim 1, wherein the body comprises a driving portion, and a linkage member is fixedly disposed on the driving portion.

9. The motion module according to claim 1, wherein the fastener comprises a guide structure, and the guide structure is configured to selectively abut against a pushing member of a fixed object; or the fastener further comprises a fastening hook, and the fastening region is formed between the fastening hook and the guide structure.

10. The motion module according to claim 1, wherein the motion module further comprises a pivot member, and the fastener is pivotally connected to the object through the pivot member; or the motion module further comprises an intermediate member disposed between the body and the object and fixed relative to the object, and the fastener is pivoted to the intermediate member through the pivot member; or the intermediate member is formed with a fixing hole, the motion module further comprises a fixing member, the fixing member is slidably disposed on the sliding limit structure, and the fixing member is fixedly disposed in the fixing hole.

11. The motion module according to claim 1, further comprising an intermediate member, wherein the intermediate member is disposed between the body and the object and formed with a plurality of fixing holes; or the motion module further comprises a fixing member, the fixing member is slidably disposed on the sliding limit structure, a plurality of the sliding limit structures and a plurality of the fixing members are provided, respectively, the plurality of sliding limit structures are disposed at intervals, and each of the plurality of fixing members is disposed on each of the plurality of sliding limit structures.

12. The motion module according to claim 1, further comprising a locking member, wherein the body is further formed with a locking portion, and the locking member runs through the locking portion.

13. The motion module according to claim 1, wherein the body further comprises a pulling portion, and the pulling portion is configured for a user to pull so as to slide the body.

14. The motion module according to claim 1, wherein one of the object and a fixed object is a detachable electronic device, a computer, a chip, a heat dissipation component, a plastic member or a metal member, or the other of the object and the fixed object is a chassis, a motherboard, a cabinet, a slide rail or a wall.

15. The motion module according to claim 1, wherein the body comprises a driving portion, the fastener further comprises a driven portion, and the fastening region is configured to be fastened to at least one part of a fixed object; and the motion module further comprises a linkage member and a fixing member, the linkage member is pivotally connected to the driving portion and the driven portion, and the fixing member is slidably disposed on the sliding limit structure; or the driving portion comprises a rack, the driven portion comprises a plurality of engaging teeth, the linkage member is a gear and engages with the rack and the plurality of engaging teeth.

16. The motion module according to claim 1, wherein the body is slidably connected to an intermediate member, the body comprises a driving portion, the fastener comprises a fastening portion and a driven portion, and the driven portion engages with the driving portion so as to enable the fastening portion to perform fastening or unfastening; or the driving portion is a rack; or the driven portion is a plurality of engaging teeth.

17. The motion module according to claim 1, wherein the body comprises a driving portion, the fastener comprises a fastening portion and a driven portion, and the driven portion engages with the driving portion so as to enable the fastening portion to perform fastening or unfastening; or the driving portion is a rack; or the driven portion is a plurality of engaging teeth.

18. The motion module according to claim 1, further comprising a locking member, running through the body and the object, wherein the locking member moves to push against the object so as to enable the body to drive the fastener to move; or the locking member has a thread and is screwed to the object, and when the locking member rotates relative to the object, an acting force of the locking member pushes against and drives the body and the fastener to move.

19. The motion module according to claim 1, wherein the body further comprises a connecting portion and is formed with two sliding limit structures; two fasteners are connectable to the body and formed with two fastening regions, and the fastening regions are each configured to be fastened to a fixed object; two fixing members are slidably disposed on the sliding limit structure and fixed relative to the object; and a locking member runs through the connecting portion of the motion module and the object, wherein the locking member moves to push against the object so as to enable the body to drive the fasteners to move; or the locking member has a thread and is screwed to the object, and when the locking member rotates relative to the object, an acting force of the locking member pushes against and drives the body and the fasteners to move.

20. The motion module according to claim 1, further comprising an intermediate member, wherein the body comprises a base, the fastener further comprises a driven portion, the base and the driven portion are driven or disposed at an angle of nearly 90 degrees or at 90 degrees, or wherein the intermediate member is bent or curved to accommodate the driven portion.
